(19) United States
(12) Patent Application Publication
(10) Pub. No.: US 2011/0316523 A1
(43) Pub. Date: Dec. 29, 2011

(54) AVOMETER

(76) Inventors: Hsin-Chen Ko, Taipei (TW); Cho-Chun Lin, Yunlin (TW)

(21) Appl. No.: 12/825,994

(22) Filed: Jun. 29, 2010

(51) Int. Cl. G01R 15/08

(52) U.S. Cl. 324/115

(57) ABSTRACT

An avometer includes a measurement main body. The measurement main body includes a rotary knob for selecting a measurement item, a display, and a navigator. The rotary knob is used for an operator to select one of a current measurement mode, a voltage measurement mode, a resistance measurement mode, and a diode measurement mode before performing an operation. The display is used for displaying information and measured data of the measurement mode selected by the rotary knob. The navigator is used for switching the information of the measurement mode, and displaying the information on the display.

### BACKGROUND OF THE INVENTION

1. Field of the Invention

The present invention relates to an avometer, which has a simple structure and is easy to operate.

2. Related Art

Conventional avometers can be generally divided into two types, that is, electronic liquid crystal display (LCD) avometers and mechanical avometers. Except for the difference in display mode, common avometers are all provided with operation knobs for multi-stage function switching and function indications marked around the operation knobs, such that according to the items to be detected, an operator can manually move and switch the knobs to select a related electrical property and a position within the scope of value to be measured.

However, the above measurement method of manually moving and switching the knobs to select a related electrical property and a position within the scope of value to be measured still requires the user to be quite familiar with electrical measurement. If a beginner or person who is not familiar with the operation switches the knob to an incorrect position, an error value will be obtained, or even the avometer will be damaged in case of high voltage or high current, which also endangers the safety of the operator. Although avometers currently available on the market can solve the above disadvantage, the structural design of either the existing electronic LCD or mechanical avometer still adopts the measurement method of manually moving and switching the knobs to select a related electrical property and a position within the scope of value to be measured before measurement. Although the measurement method is simple and clear for the operator, the design of the operation buttons requiring manual switching has been used for years without any change. In order to make the operation interface of the avometer more intuitive while maintaining a simple and quick operation, a new operation interface of an avometer is provided by the inventor through further research, development and improvement.

### SUMMARY OF THE INVENTION

Accordingly, the present invention is mainly directed to an avometer, which has a simple structure and is easy to operate.

In order to achieve the above objectives, the present invention provides an avometer, which includes a measurement main body. The measurement main body includes a rotary knob for selecting a measurement item, a display, and a navigator. The rotary knob is used for an operator to select one of a current measurement mode, a voltage measurement mode, a resistance measurement mode, and a diode measurement mode before performing an operation. The display is used for displaying information and measured data of the measurement mode selected by the rotary knob. The navigator is used for switching the information of the measurement mode, and displaying the information on the display.

In the implementation, a current clamp for receiving a current-carrying conductor is disposed at an upper end of the measurement main body.

In the implementation, the measurement main body is provided with a jack for inserting a test probe therein.

In the implementation, the information of the measurement mode comprises direct current (DC), alternating current (AC), maximum, minimum, and range.

In the implementation, the navigator includes toggling modes in up, down, left, and right directions.

In order to make the present invention more comprehensible, the present invention is described in detail below through an embodiment.

### BRIEF DESCRIPTION OF THE DRAWINGS

The present invention will become more fully understood from the detailed description given herein below for illustration only, and thus are not limitative of the present invention, and wherein:

FIG. 1 is a three-dimensional outside view of an avometer according to an embodiment of the present invention;

FIG. 2 is a schematic state diagram of the avometer in a measurement mode according to the embodiment of the present invention;

FIG. 3 is a schematic state diagram of the avometer after the measurement mode is switched according to the embodiment of the present invention; and

FIG. 4 is a schematic state diagram of an operation of toggling a navigator according to the present invention.

### DETAILED DESCRIPTION OF THE INVENTION

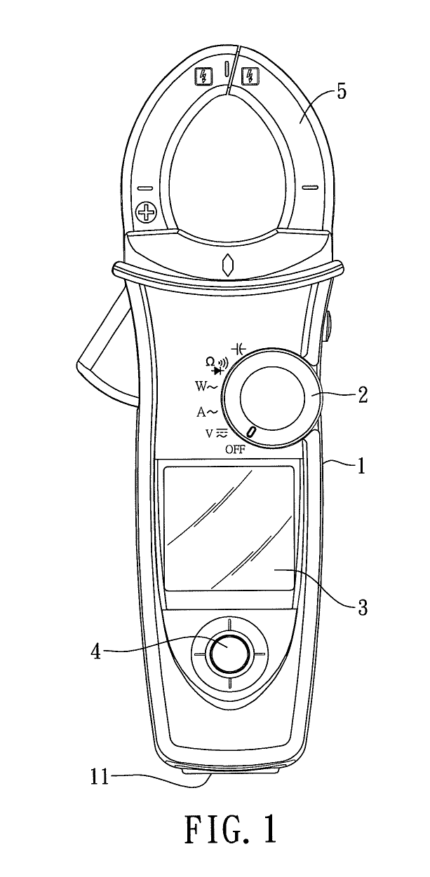

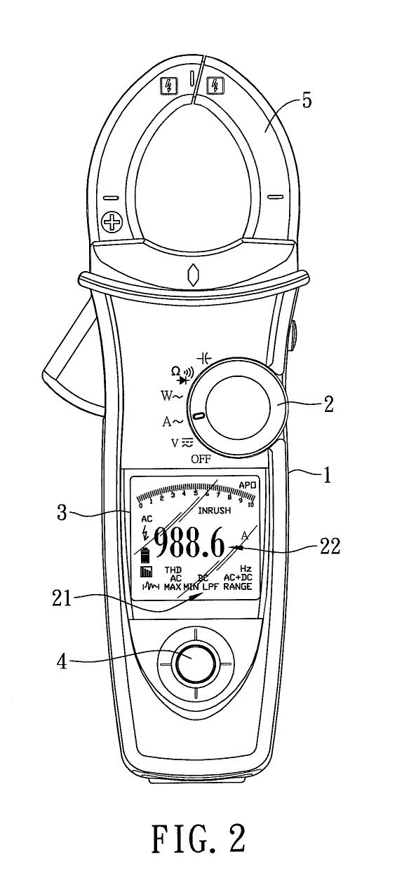

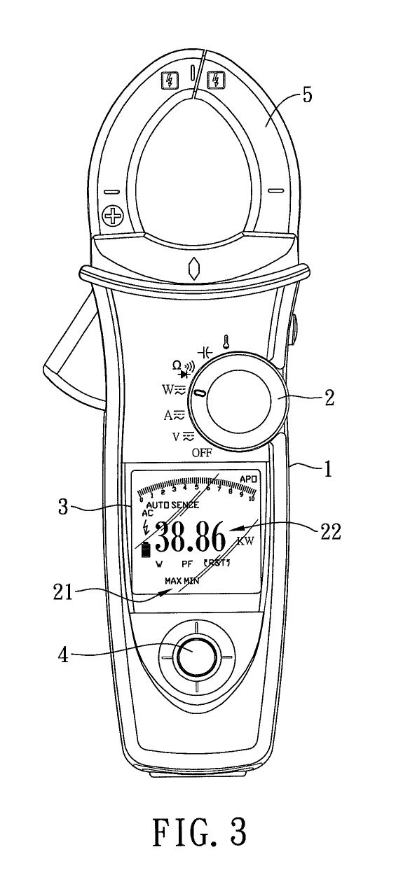

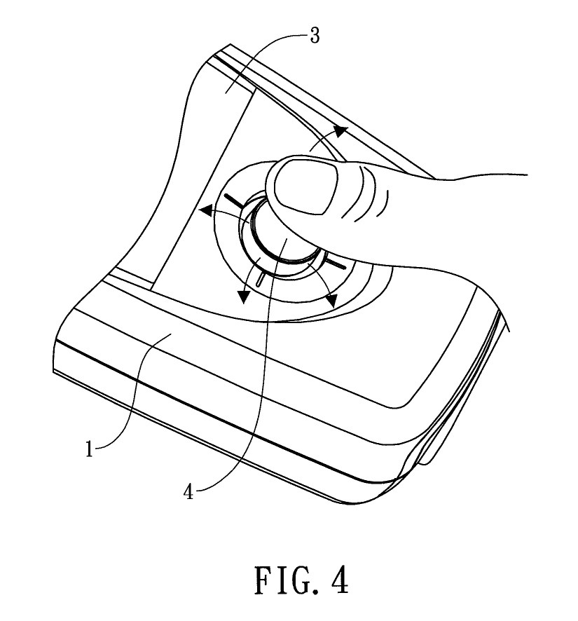

Referring to FIGS. 1 to 4, an avometer of the present invention includes a measurement main body 1, and the measurement main body 1 includes a rotary knob 2 for selecting a measurement item, a display 3, and a navigator 4.

A current clamp 5 for receiving a current-carrying conductor is disposed at an upper end of the measurement main body 1. The measurement main body 1 is provided with a jack 11 for inserting a test probe therein. The rotary knob 2 is used for an operator to select one of a current measurement mode, a voltage measurement mode, a resistance measurement mode, and a diode measurement mode before performing an operation. The display 3 is used for displaying information 21 and measured data 22 of the measurement mode selected by the rotary knob 2. The information 21 of the measurement mode includes direct current (DC), alternating current (AC), maximum, minimum, and range. The navigator 4 is used for switching the information 21 of the measurement mode, and displaying the information on the display 3. The navigator 4 includes toggling modes in up, down, left, and right directions.

In the implementation, after rotating the rotary knob 2 to a desired position for measurement, the operator can perform measurement via the test probe or the current clamp 5. By toggling the navigator 4 in up, down, left, and right directions, the operator can switch the information 21 of the measurement mode, and display the measured data 22 on the display 3.

Therefore, with the structural design of the navigator according to the present invention, the user can clearly know the measured data through the toggling modes in up, down, left, and right directions. Thus, the operation interface is more intuitive, and meanwhile the advantage of simple and quick operation is maintained.

While the present invention has been described with reference to the embodiments and technical means thereof, various changes and modifications can be made based on the disclosure or teachings described herein. Any equivalent changes made based on the concepts of the present invention having their effect without departing from the spirit encompassed by the specification and drawings should be construed as falling within the scope of the invention as defined by the appended claims.

According to the aforementioned disclosure, the present invention surely can achieve the expected objectives to provide an avometer, which has industrial applicability. Thus, the application for a patent is filed according to the law.

What is claimed is:

1. An avometer, comprising a measurement main body, wherein the measurement main body comprises:
a rotary knob for selecting a measurement item, for an operator to select one of a current measurement mode, a voltage measurement mode, a resistance measurement mode, and a diode measurement mode before performing an operation;
a display, for displaying information and measured data of the measurement mode selected by the rotary knob; and
a navigator, for switching the information of the measurement mode, and displaying the information on the display.

2. The avometer according to claim 1, wherein a current clamp for receiving a current-carrying conductor is disposed at an upper end of the measurement main body.

3. The avometer according to claim 1, wherein the measurement main body is provided with a jack for inserting a test probe therein.

4. The avometer according to claim 1, wherein the information of the measurement mode comprises direct current (DC), alternating current (AC), maximum, minimum, and range.

5. The avometer according to claim 1, wherein the navigator comprises toggling modes in up, down, left, and right directions.
